(19) United States
(12) Patent Application Publication
(10) Pub. No.: US 2026/0239626 A1
(43) Pub. Date: Aug. 13, 2026

(54) MEMORY STRUCTURE AND METHOD FOR MANUFACTURING THE SAME

(71) Applicant: MACRONIX INTERNATIONAL CO., LTD., Hsinchu (TW)

(72) Inventors: Erh-Kun LAI, Taichung County (TW); Cheng-Lin SUNG, Hsinchu County (TW); Hsiang-Lan LUNG, Kaohsiung City (TW)

(21) Appl. No.: 19/050,157

(22) Filed: Feb. 11, 2025

(51) Int. Cl. H10B 63/00; H10N 70/00

(52) U.S. Cl. CPC H10B 63/24; H10N 70/021; H10N 70/841

(57) ABSTRACT

A memory structure is provided. The memory structure includes a stack, a plurality of first electrodes, and a plurality of second electrodes. The stack includes first levels and second levels arranged alternately, wherein the first levels include an insulating material, and the second levels include an ovonic threshold switching material. The first electrodes penetrate through the stack. The second electrodes are disposed in the second levels. Each row of the second electrodes has a continuous arc configuration.

### TECHNICAL FIELD

This disclosure relates to a memory structure and a method for manufacturing the same. More particularly, this disclosure relates to a memory structure with an ovonic threshold switching (OTS) material and a method for manufacturing the same.

### BACKGROUND

In semiconductor technology, shrinkage of device and feature sizes, improvement in electrical characteristics, such as operation speed, efficiency, and the like, and reduction of cost are always important goals. For decreasing the sizes of semiconductor devices, various 3D structures have been developed for different kinds of devices. In addition, new materials have been introduced for development of new device types and/or replacement of conventional electronic components. For example, ovonic threshold switching (OTS) materials show potential to meet the selector requirements from both electrical and 3D integration points of view. Some ovonic threshold switching materials further exhibit well “remembrance” properties. This allows for the development of OTS memory.

### SUMMARY

In this disclosure, a new memory structure for OTS memory and a method for manufacturing the same are provided.

A memory structure according to the disclosure comprises a stack, a plurality of first electrodes, and a plurality of second electrodes. The stack comprises first levels and second levels arranged alternately, wherein the first levels comprise an insulating material, and the second levels comprise an ovonic threshold switching material. The first electrodes penetrate through the stack. The second electrodes are disposed in the second levels. Each row of the second electrodes has a continuous arc configuration.

A method for manufacturing a memory structure according to the disclosure comprises following steps. First, an initial stack is formed on an underlying structure. The initial stack is formed by alternately forming first levels with an insulating material and second levels with an ovonic threshold switching material on the underlying structure. Next, a plurality of holes are formed through the initial stack. The holes comprise first holes arranged in first rows and second holes arranged in second rows, and the first rows and the second rows are arranged alternately. Then, the second holes are masked. A plurality of first electrodes are formed in the first holes, respectively. Thereafter, the first holes with the first electrodes are masked. A plurality of second electrodes are formed in the second levels through the second holes.

### BRIEF DESCRIPTION OF THE DRAWINGS

FIGS. 1A-1B illustrate a memory structure according to the disclosure.

FIGS. 2A-2B to FIGS. 11A-11B illustrate various stages of a method for manufacturing a memory structure according to the disclosure.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

Various embodiments will be described more fully hereinafter with reference to accompanying drawings. The description and the drawings are provided for illustrative only, and not intended to result in a limitation. For clarity, the elements may not be drawn to scale. In addition, some elements and/or reference numerals may be omitted from some drawings. It is contemplated that the elements and features of one embodiment can be beneficially incorporated in another embodiment without further recitation.

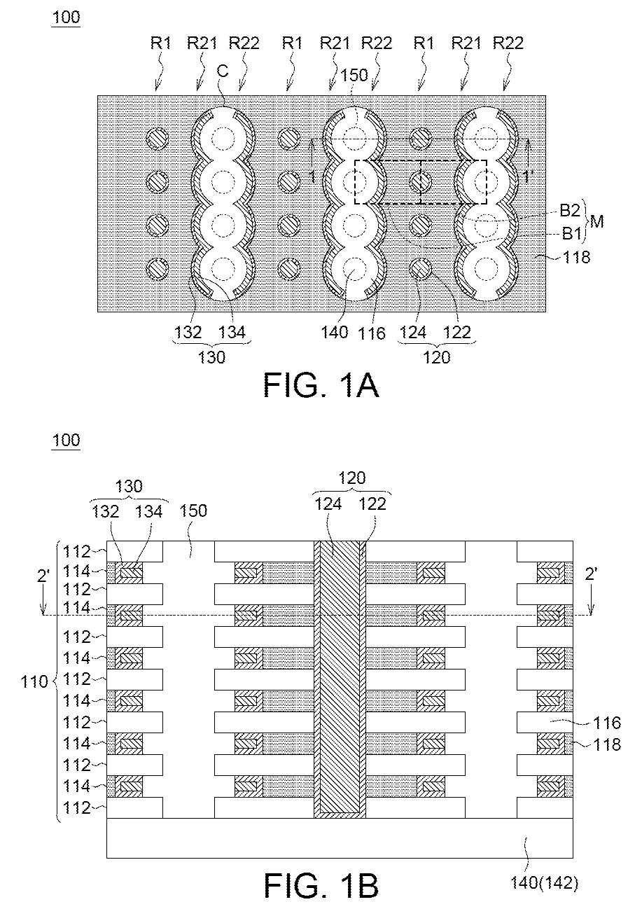

FIGS. 1A-1B show a memory structure 100 according to the disclosure, wherein FIG. 1A is a horizontal cross-sectional view of the memory structure 100 along line 2-2’, and FIG. 1B is a vertical cross-sectional view of the memory structure 100 along line 1-1’.

The memory structure 100 comprises a stack 110, a plurality of first electrodes 120, and a plurality of second electrodes 130. The stack 110 comprises first levels 112 and second levels 114 arranged alternately, wherein the first levels 112 comprise an insulating material 116, and the second levels 114 comprise an ovonic threshold switching material 118. The first electrodes 120 penetrate through the stack 110. The second electrodes 130 are disposed in the second levels 114. Each row (R21/R22) of the second electrodes 130 has a continuous arc configuration.

Specifically, the memory structure 100 can comprise an underlying structure 140, and the stack 110 can be disposed on the underlying structure 140. The underlying structure 140 can comprise a substrate 142. While not shown in the drawings, the underlying structure 140 can further comprise one or more of device layers, such as but not limited to a CMOS layer, connection conductors, such as but not limited to conductive lines and vias, dielectric layers, or the like disposed on or in the substrate 142 depending on the device design.

The stack 110 comprises the alternating first and second levels 112 and 114. The first levels 112 comprise the insulating material 116. The insulating material 116 can be oxide, but not limited thereto. The second levels 114 comprise the ovonic threshold switching material 118. The ovonic threshold switching material 118 can be any suitable material composed of amorphous chalcogenide-based non-metallic materials. For example, the ovonic threshold switching material 118 can be a material based on Te-As-Ge-Si system, in which Ge, Si and As concentrations can be tuned to achieve a good endurance. The ovonic threshold switching material 118 can be a Se-based chalcogenide, too. AsSeGe with one or more dopants selected from the group consisting of B, C, S, Si, and In may also be a suitable ovonic threshold switching material 118. However, the disclosure is not limited thereto.

The first electrodes 120 penetrate through the stack 110 and land on the underlying structure 140. In a horizontal cross section, the first electrodes 120 are arranged in rows R1, as shown in FIG. 1A. The first electrodes 120 can have a column shape. According to some embodiments, each of the first electrodes 120 can comprise an electrode layer 122 and a conductor pillar 124. The electrode layer 122 surrounds the conductor pillar 124. The electrode layer 122 can be further disposed on a bottom surface of the conductor pillar 124. The electrode layer 122 can have a better interfacial property with the insulating material 116 and the ovonic threshold switching material 118 in the stack 100 than the conductor pillar 124, and the conductor pillar 124 can have a better electrical conductivity than the electrode layer 122. However, the disclosure is not limited thereto.

The second electrodes 130 are disposed in the second levels 114. In a horizontal cross section, the second electrodes 130 are arranged in rows R21 and R22, as shown in FIG. 1A. The rows R21 and R22 have a same row direction as the rows R1. The continuous arc configuration of each row R21/R22 of the second electrodes 130 is formed of a plurality of arc portions connected to each other with openings facing a same direction. Each of the arc portions can correspond to one second electrode 130. The direction which the openings of the arc portions face is opposite to the first electrodes 120. As shown in FIG. 1A, between each two adjacent rows R1 of the first electrodes 120, there can be two rows R21 and R22 of the second electrodes 130. Corresponding two arc portions respectively from the two rows R21 and R22 of the second electrodes 130 can form parts of a virtual ring C. According to some embodiments, each of the second electrodes 130 can comprise an electrode layer 132 and a conductor arc 134. The electrode layer 132 is disposed on a sidewall of the conductor arc 134 which is opposite to an opening direction of the conductor arc 134. The electrode layer 132 can be further disposed on a top surface and a bottom surface of the conductor arc 134, as shown in FIG. 1B. Similarly, the electrode layer 132 can have a better interfacial property with the insulating material 116 and the ovonic threshold switching material 118 in the stack 100 than the conductor arc 134, and the conductor arc 134 can have a better electrical conductivity than the electrode layer 132. However, the disclosure is not limited thereto.

In some embodiments, the memory structure 100 can comprise a filling insulating material 150. The filling insulating material 150 fills the spaces between the each two rows R21 and R22 of the second electrodes 130.

According to some embodiments, the ovonic threshold switching material 118 in a second level 114 can be a word line plane. The first electrodes 120 can be connected to a bit line. As such, each of the first electrodes 120, corresponding two of the second electrodes 130 at each side of said each of the first electrodes 120, and the ovonic threshold switching material 118 between said each of the first electrodes 120 and said corresponding two of the second electrodes 130 can form a two-bit memory cell M. The two bits are indicated by frame B1 and frame B2, respectively, and they have an identical distance across the ovonic threshold switching material 118. In such a manner, the memory structure 100 can be used to provide a 2-bits per cell OTS memory.

Attention is now directed to a method for manufacturing a memory structure according to the disclosure. The method comprises following steps. First, an initial stack is formed on an underlying structure. The initial stack is formed by alternately forming first levels with an insulating material and second levels with an ovonic threshold switching material on the underlying structure. Next, a plurality of holes are formed through the initial stack. The holes comprise first holes arranged in first rows and second holes arranged in second rows, and the first rows and the second rows are arranged alternately. Then, the second holes are masked. A plurality of first electrodes are formed in the first holes, respectively. Thereafter, the first holes with the first electrodes are masked. A plurality of second electrodes are formed in the second levels through the second holes.

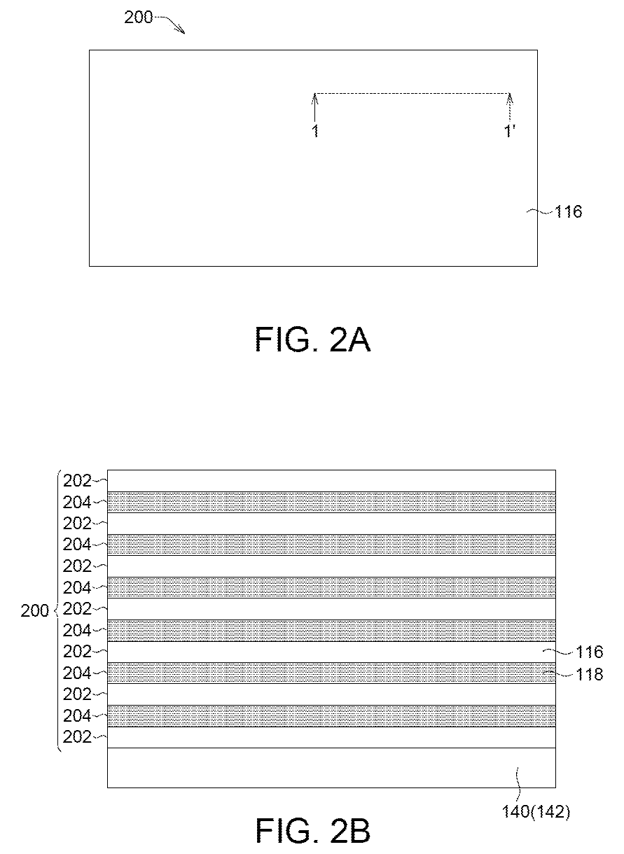

FIGS. 2A-2B to FIGS. 11A-11B illustrate various stages of the method for manufacturing the memory structure 100. Referring to FIGS. 2A-2B, a structure at a beginning stage of the method is shown, wherein FIG. 2A is a top view of the structure, and FIG. 2B is a vertical cross-sectional view of the structure along line 1-1’. An initial stack 200 is formed on an underlying structure 140. The initial stack 200 can be formed by alternately forming first levels 202 with an insulating material 116 and second levels 204 with an ovonic threshold switching material 118 on the underlying structure 140. As described above, the insulating material 116 can be oxide, and the ovonic threshold switching material 118 can be a material based on Te-As-Ge-Si system, a Se-based chalcogenide, or a doped AsSeGe, but not limited thereto. In this method, the ovonic threshold switching material 118 can be provided by not only the CVD process, which is typically used for forming an OTS layer, but also the PVD process. Since the PVD OTS film purity is better than the CVD/ALD OTS, it would provide better device performance than the CVD/ALD OTS.

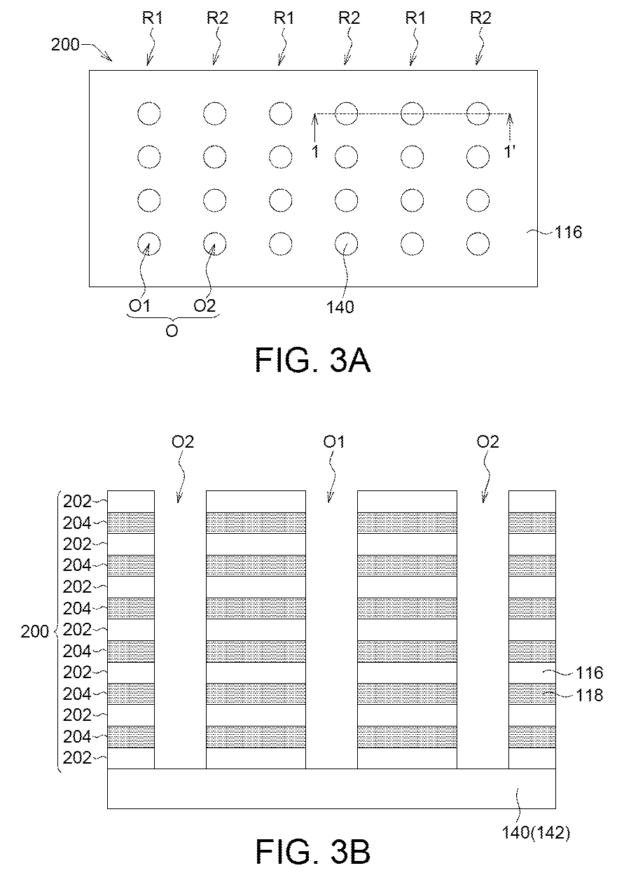

FIGS. 3A-3B shows the structure at a subsequent stage of the method, wherein FIG. 3A is a top view of the structure, and FIG. 3B is a vertical cross-sectional view of the structure along line 1-1’. A plurality of holes O are formed through the initial stack 200. The holes O comprise first holes O1 arranged in first rows R1 and second holes O2 arranged in second rows R2. The first rows R1 and the second rows R2 are arranged alternately.

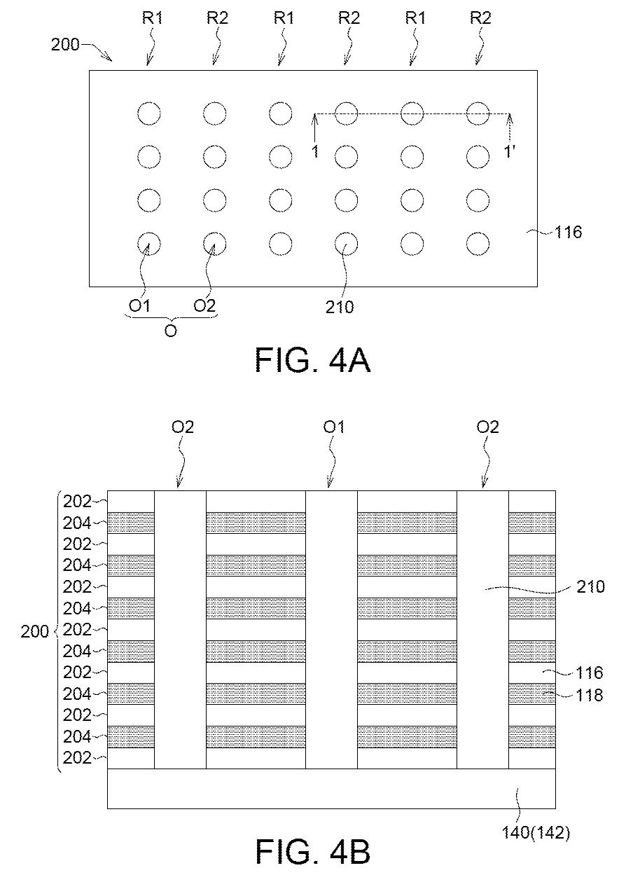

FIGS. 4A-4B shows the structure at a subsequent stage of the method, wherein FIG. 4A is a top view of the structure, and FIG. 4B is a vertical cross-sectional view of the structure along line 1-1’. A sacrificial material 210 is filled into the holes O. The sacrificial material 210 can be carbon, but not limited thereto.

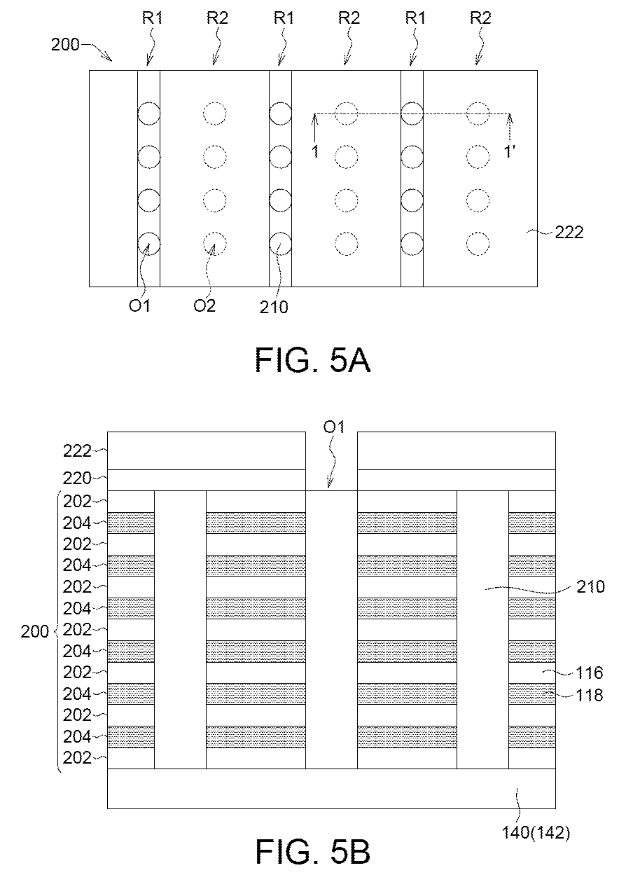

FIGS. 5A-5B shows the structure at a subsequent stage of the method, wherein FIG. 5A is a top view of the structure, and FIG. 5B is a vertical cross-sectional view of the structure along line 1-1’. A cap layer 220 is formed on the initial stack 200 and covering the holes O. The cap layer 220 can be formed of oxide. A deposition process and an optional planarization process, such as s CMP process, can be conducted for forming of the cap layer 220. A mask layer 222 is formed on the cap layer 220 at positions above the second holes O2. The mask layer 222 can be formed of photo resist. In this manner, the second holes O2 are masked. Then, portions of the cap layer 220 on the sacrificial material 210 in the first holes O1 are removed.

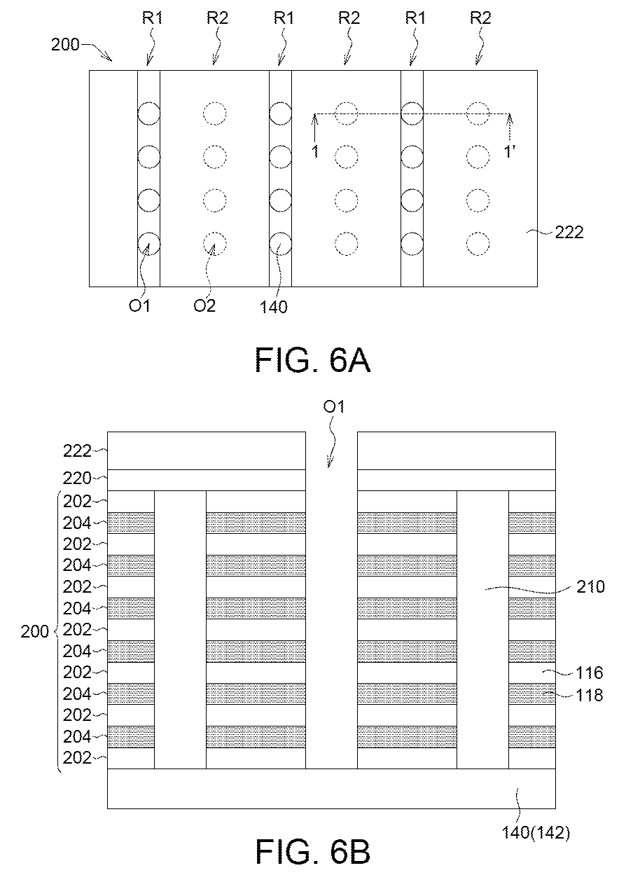

FIGS. 6A-6B shows the structure at a subsequent stage of the method, wherein FIG. 6A is a top view of the structure, and FIG. 6B is a vertical cross-sectional view of the structure along line 1-1’. The sacrificial material 210 in the first holes O1 is removed.

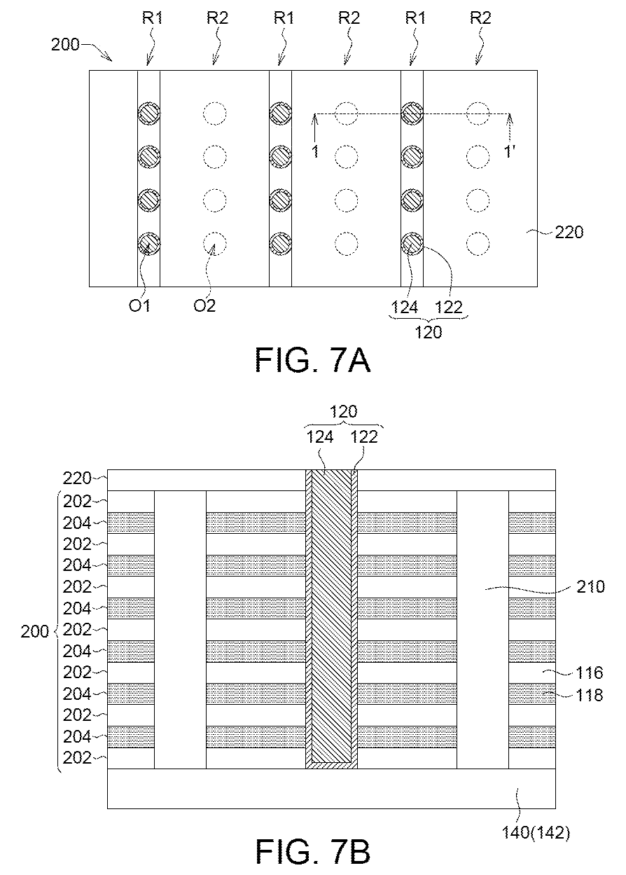

FIGS. 7A-7B shows the structure at a subsequent stage of the method, wherein FIG. 7A is a top view of the structure, and FIG. 7B is a vertical cross-sectional view of the structure along line 1-1’. A plurality of first electrodes 120 are formed in the first holes O1, respectively. Specifically, electrode layers 122 can be formed on sidewalls and bottoms of the first holes O1. Then, a conductive material is filled into remaining spaces of the first holes O1. As such, conductor pillars 124 are formed. The conductor pillars 124 together with the electrode layers 122 form the first electrodes 120 in a composite manner. The portion of the structure above the cap layer 220 is removed by, for example, a CMP process.

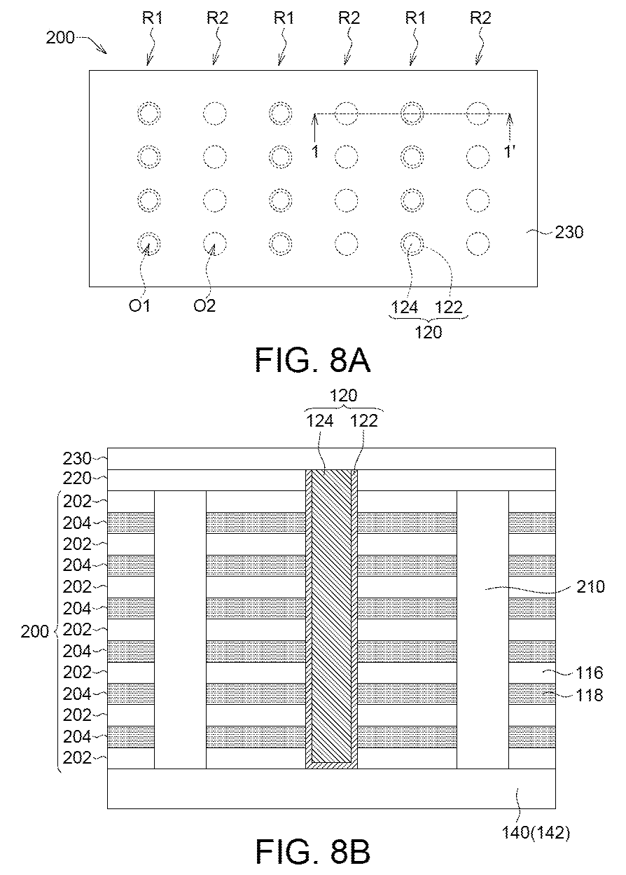

FIGS. 8A-8B shows the structure at a subsequent stage of the method, wherein FIG. 8A is a top view of the structure, and FIG. 8B is a vertical cross-sectional view of the structure along line 1-1’. A cap layer 230 is formed on the initial stack 200 and covering the holes O. In the case that the cap layer 220 remains in the structure, the cap layer 230 can be formed on the cap layer 220. The cap layer 230 can be formed of oxide. A deposition process and an optional planarization process, such as s CMP process, can be conducted for forming of the cap layer 230.

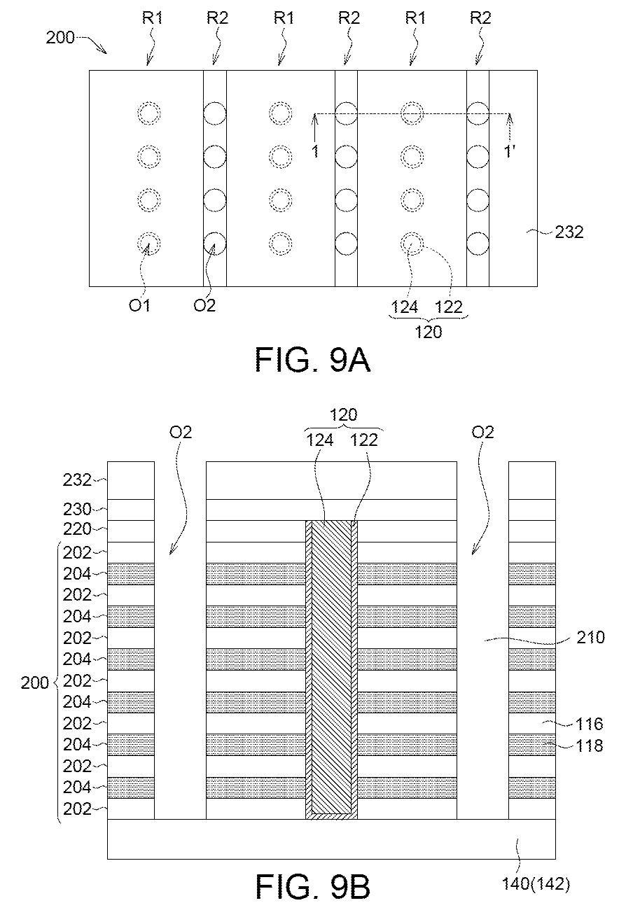

FIGS. 9A-9B shows the structure at a subsequent stage of the method, wherein FIG. 9A is a top view of the structure, and FIG. 9B is a vertical cross-sectional view of the structure along line 1-1’. A mask layer 232 is formed on the cap layer 230 at positions above the first holes O1 with the first electrodes 120. The mask layer 232 can be formed of photo resist. In this manner, the first holes O1 with the first electrodes 120 are masked. Then, portions of the cap layer 230 on the sacrificial material 210 in the second holes O2 are removed. Portions of the cap layer 220 on the sacrificial material 210 in the second holes O2, if exist, are also removed. Also, the sacrificial material 210 in the second holes O2 are removed.

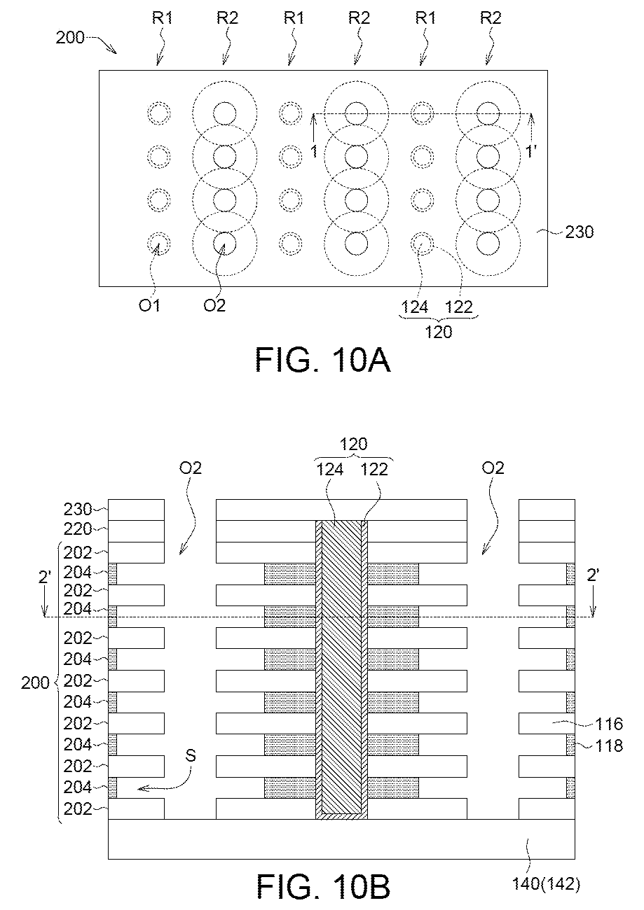

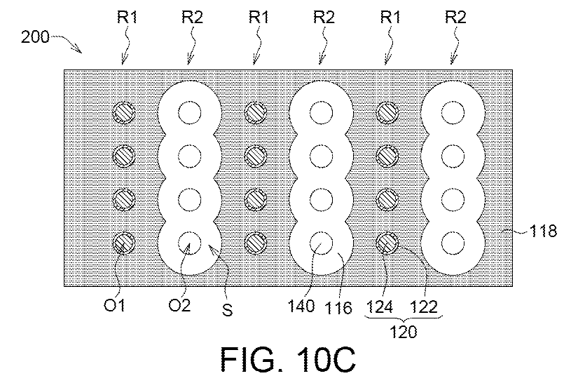

FIGS. 10A-10C shows the structure at a subsequent stage of the method, wherein FIG. 10A is a top view of the structure, FIG. 10B is a vertical cross-sectional view of the structure along line 1-1’, and FIG. 10C is a horizontal cross-sectional view of the structure along line 2-2’. The mask layer 232 is removed. Portions of the ovonic threshold switching material 118 in the second levels 204 are isotropically removed through the second holes O2 so as to form extended spaces S in the second levels 204, such as by a time controlled isotropic etching process. The extended spaces S can be in connection with each other in a row direction of the second rows R2 of the second holes O2, as shown in FIG. 10C.

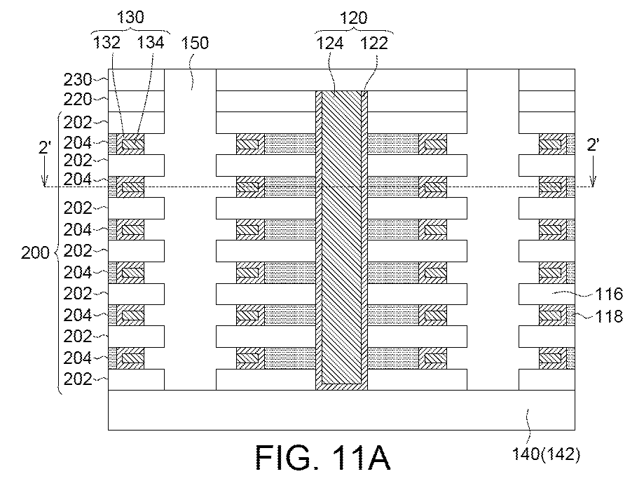

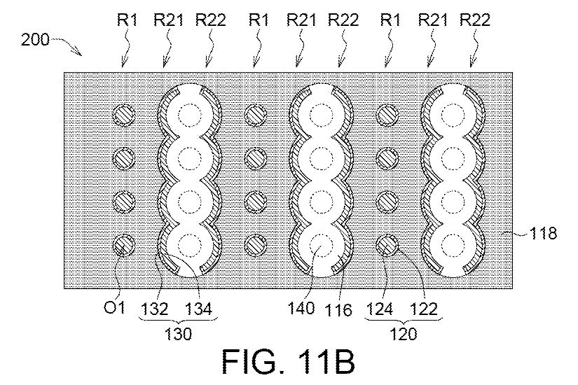

FIGS. 11A-11B shows the structure at a subsequent stage of the method, wherein FIG. 11A is a vertical cross-sectional view of the structure along line 1-1’, and FIG. 11B is a horizontal cross-sectional view of the structure along line 2-2’. A plurality of second electrodes 130 are formed in the second levels 204 through the second holes O2. Specifically, electrode layers 132 can be formed on sidewalls and tops and bottoms of the extended spaces S. Then, a conductive material is provided into remaining spaces of the extended spaces S. The conductive material forms a plurality of conductor arcs 134, and the conductor arcs 134 in a same row R21/R22 along the row direction are connected to each other. The conductor arcs 134 together with the electrode layers 132 form the second electrodes 130 in a composite manner. As such, each row R21/R22 of the second electrodes 130 has a continuous arc configuration. In some embodiments, an etching back process can be conducted, and portions of the extended spaces S are exposed again. Then, a filling insulating material 150 can be filled into the second holes O2 and the exposed portions of the extended spaces S. The filling insulating material 150 can be oxide, but not limited thereto. As such, the memory structure 100 can be fabricated. It is understood that other suitable processes for 3D semiconductor structure can be applied in the method. For example, the stack (said initial stack 200) and the holes O can be formed applying a multi-tier overlay process, but not limited thereto.

In the method according to the disclosure, only holes are formed penetrating the stack (said initial stack 200). There is no trench formed penetrating the stack. In other words, line definition is not used in the lithography processes in the method according to the disclosure, only hole definition is applied. As such, a misalignment issue between holes and trenches will not happen in the method according to the disclosure. Misalignment is a very big issue in 3D multi-layer process, such as 3D OTS or 3D NAND. The method according to the disclosure would provide self-aligned process to prevent from misalignment of hole to hole, hole to line, or line to hole. In addition, the holes can be formed at a higher density with less possibility of collapse. Thus, the volume can be further decreased compared with a conventional 3D OTS memory applying the line definition.

Further, in the method according to the disclosure, the ovonic threshold switching material can be provided using a PVD process. Since the PVD OTS film purity is better than CVD/ALD OTS, it would provide better device performance than the CVD/ALD OTS. It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A memory structure, comprising:
a stack comprising first levels and second levels arranged alternately, wherein the first levels comprise an insulating material, and the second levels comprise an ovonic threshold switching material;
a plurality of first electrodes penetrating through the stack; and
a plurality of second electrodes disposed in the second levels, wherein each row of the second electrodes has a continuous arc configuration.

2. The memory structure according to claim 1, wherein the continuous arc configuration is formed of a plurality of arc portions connected to each other with openings facing a same direction.

3. The memory structure according to claim 2, wherein the direction which the openings of the arc portions face is opposite to the first electrodes.

4. The memory structure according to claim 1, wherein between each two adjacent rows of the first electrodes, there are two rows of the second electrodes.

5. The memory structure according to claim 4, wherein corresponding two arc portions respectively from the two rows of the second electrodes form parts of a virtual ring.

6. The memory structure according to claim 1, wherein each of the first electrodes comprises an electrode layer and a conductor pillar, and the electrode layer surrounds the conductor pillar.

7. The memory structure according to claim 6, wherein the electrode layer is further disposed on a bottom surface of the conductor pillar.

8. The memory structure according to claim 1, wherein each of the second electrodes comprises an electrode layer and a conductor arc, and the electrode layer is disposed on a sidewall of the conductor arc which is opposite to an opening direction of the conductor arc.

9. The memory structure according to claim 8, wherein the electrode layer is further disposed on a top surface and a bottom surface of the conductor arc.

10. The memory structure according to claim 1, wherein each of the first electrodes, corresponding two of the second electrodes at each side of said each of the first electrodes, and the ovonic threshold switching material between said each of the first electrodes and said corresponding two of the second electrodes form a two-bit memory cell.

11. A method for manufacturing a memory structure, comprising:
forming an initial stack on an underlying structure, wherein the initial stack is formed by alternately forming first levels with an insulating material and second levels with an ovonic threshold switching material on the underlying structure;
forming a plurality of holes through the initial stack, wherein the holes comprise first holes arranged in first rows and second holes arranged in second rows, and the first rows and the second rows are arranged alternately;
masking the second holes;
forming a plurality of first electrodes in the first holes, respectively;
masking the first holes with the first electrodes; and
forming a plurality of second electrodes in the second levels through the second holes.

12. The method according to claim 11, further comprising:
before masking the second holes, filling a sacrificial material into the holes.

13. The method according to claim 12, wherein masking the second holes comprising:
forming a cap layer on the initial stack and covering the holes; and
forming a mask layer on the cap layer at positions above the second holes; and
wherein the method further comprises:
after masking the second holes, removing portions of the cap layer on the sacrificial material in the first holes and removing the sacrificial material in the first holes.

14. The method according to claim 12, wherein masking the first holes comprising:
forming a cap layer on the initial stack and covering the holes; and
forming a mask layer on the cap layer at positions above the first holes with the first electrodes; and
wherein the method further comprises:
after masking the first holes, removing portions of the cap layer on the sacrificial material in the second holes and removing the sacrificial material in the second holes.

15. The method according to claim 11, wherein forming the first electrodes in the first holes comprises:
forming electrode layers on sidewalls and bottoms of the first holes; and
filling a conductive material into remaining spaces of the first holes.

16. The method according to claim 11, further comprising:
before forming the second electrodes in the second levels through the second holes, isotropically removing portions of the ovonic threshold switching material in the second levels through the second holes so as to form extended spaces in the second levels.

17. The method according to claim 16, wherein the extended spaces are in connection with each other in a row direction of the second rows of the second holes.

18. The method according to claim 16, wherein forming the second electrodes in the second levels through the second holes comprises:
forming electrode layers on sidewalls and tops and bottoms of the extended spaces; and
providing a conductive material into remaining spaces of the extended spaces.

19. The method according to claim 18, wherein the conductive material forms a plurality of conductor arcs, and the conductor arcs in a same row along a row direction are connected to each other.

20. The method according to claim 11, wherein each row of the second electrodes has a continuous arc configuration.
